(19) United States
(12) Patent Application Publication
(10) Pub. No.: US 2009/0040165 A1
(43) Pub. Date: Feb. 12, 2009

(54) Amplifying circuit and display unit

(75) Inventor: Atsushi Shimatani, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/219,431

(22) Filed: Jul. 22, 2008

(30) Foreign Application Priority Data
Aug. 8, 2007 (JP) 206224/2007

(51) Int. Cl. G09G 3/36; H03F 3/45

(52) U.S. Cl. 345/98; 330/252

(57) ABSTRACT

Provided is an amplifying circuit and display unit (for example, a liquid crystal display) which achieves reductions in an area and power consumption without needing to build up complicated logic, while maintaining properties, as compared with the existing amplifying circuit and display unit. In the amplifying circuit, a voltage follower is divided into components including an input stage amplifying part for high voltage, an input stage amplifying part for low voltage and multiple output stage amplifying parts. Without changing an input relationship between the input stage amplifying parts for high voltage and for low voltage, an output relationship between the multiple output stage amplifying parts is changed depending on a control signal. Additionally, when the input stage amplifying part and the output stage amplifying part form one amplifying part, the amplifying part is switched to form the voltage follower in response to switching operation.

### BACKGROUND OF THE INVENTION

1. Field of the Invention

The present invention relates to an amplifying circuit and a display unit, and particularly, relates to an amplifying circuit used in an active matrix type data drive circuit (for example, a liquid crystal display drive circuit), and a display unit (for example, a liquid crystal display) that employs the amplifying circuit.

2. Description of the Related Art

An existing amplifying circuit and a display unit will be described below taking a liquid crystal display as an example. An active matrix type liquid crystal display has been known which includes: a liquid crystal panel; a liquid crystal display drive circuit disposed on an upper side of the liquid crystal panel; and a gate driver disposed on a side surface of the liquid crystal panel. In such a liquid crystal display, an amplifying circuit for driving a capacitive load of each pixel is used for a liquid crystal display drive unit.

In the liquid crystal panel, alternating current drive is performed in order to prevent application of a direct current voltage from causing sticking. The alternating current drive of the liquid crystal panel uses a drive method in which a write polarity is inverted relative to a common level for each frame, line or dot, and includes various methods such as “frame inversion,” “gate line inversion,” “data line inversion” and “dot inversion.” The “frame inversion” is a method in which the write polarity is inverted for each frame. The “gate line inversion” is a method in which the write polarity in a scanning line direction is inverted for each N gate lines (N: integer not less than 2) within a frame while the write polarity is also inverted for each frame. The “data line inversion” is a method in which the write polarity in a data line direction is kept within a frame, but is inverted for each frame. The “dot inversion” is a method in which the write polarity is inverted for each of adjacent pixels within a frame, and the write polarity is further inverted for each frame.

The present invention relates to the “gate line inversion” method and the “dot inversion” method previously described. In other words, the present invention relates to a method for writing data pieces having different polarities to each two adjacent pixels connected to the same gate line.

Hereinafter, a method of driving a general liquid crystal display will be briefly described with reference to a liquid crystal display drive circuit and a liquid crystal panel in FIG. 8.

The liquid crystal display drive circuit includes: a data register 1 that receives digital display signals R, G, and B with a predetermined number of bits, for example, 8 bits; a latch circuit 2 that latches a digital display signal in synchronization with a strobe signal (hereinafter, referred to as a strobe signal STB) generated from a horizontal synchronizing signal HSYNC for latching inputted data; a DA converter 3 consisting of N (N: integer not less than 2) digital-to-analog converters arranged in parallel; a liquid crystal grayscale voltage generating circuit 4 that has a gamma conversion property corresponding to the property of the liquid crystal used in the liquid crystal display drive unit; and an amplifying circuit 5 that buffers voltage from the DA converter 3.

The liquid crystal panel includes a TFT 6 (Thin Film Transistor, TFT 6_1 to TFT 6_N) and a pixel capacitor 7 (a pixel capacitor 7_1 to a pixel capacitor 7_N). The TFT 6 is provided at each of the intersections of data lines and scanning lines. The gates of the TFTs 6 are connected to the corresponding scanning lines, and the sources thereof are connected to the corresponding data lines. One end of each of the pixel capacitors 7 is connected to its corresponding drain of the TFT 6, and the other end thereof is connected to its corresponding COM port. Although FIG. 8 shows a configuration of the liquid crystal panel only for one line for convenience in description, an actual liquid crystal panel is provided with M (M: integer not less than 2) lines of TFTs 6 shown in FIG. 8.

When the liquid crystal display operates, a gate driver (not shown) sequentially drives the gate of each TFT in each line.

The DA converter 3 supplies the amplifying circuit 5 with a voltage obtained by digital-to-analog converting the digital display signals from the latch circuit 2. Specifically, with a decoder formed of a ROM switch (not shown) or the like, the DA converter 3 selects one of multiple reference voltages generated in the liquid crystal grayscale voltage generating circuit 4, corresponding to the digital display signals, and then supplies the reference voltage thus selected to the amplifying circuit 5.

The liquid crystal grayscale voltage generating circuit 4 includes, for example, a resistance ladder circuit that is driven by a voltage follower in order either to lower the impedance at each reference voltage point, or to adjust the reference voltage. Moreover, the liquid crystal grayscale voltage generating circuit 4 outputs a positive polarity grayscale voltage and a negative polarity grayscale voltage so as to perform the above-mentioned alternating current drive.

The amplifying circuit 5 performs impedance conversion of the positive polarity grayscale voltage and negative polarity grayscale voltage received from the DA converter 3. The amplifying circuit 5 outputs output voltages from output terminals thereof to the respective drains of the TFT 6_1 to TFT 6_N in the liquid crystal panel during writing to the pixels, and sets the output terminals of the amplifying circuit 5 to a high impedance state during charge recovery.

In the active matrix type display unit employing the dot inversion drive method, as described above, the data lines of the liquid crystal panel are driven so that the polarities of voltages applied to each adjacent pixels of a single scanning line would be different from each other, and further, are driven so that the positive polarity grayscale voltage and the negative polarity grayscale voltage would be switched for every one horizontal period. Thereby, the amplifying circuit 5 of the liquid crystal display drive circuit has a configuration in which the positive polarity grayscale voltage and the negative polarity grayscale voltage are alternately outputted from the amplifying circuit 5 so that the polarities of voltages outputted from an odd number terminal and an even number terminal would be alternated.

The existing amplifying circuit 5 will be described in more detail using FIG. 9 that is a schematic view of FIG. 2 in Japanese Patent Application Publication No. 2000-221927 (JP-A 2000-221927, below). Note that, when the liquid crystal panel has, for example, a resolution of 1280×1024 (SXGA) (one pixel consists of 3 dots, R, G, and B), use of 10 liquid crystal display drive circuits for 1280×3=3840 data lines needs 384 outputs in one liquid crystal display drive circuit. Here, for the sake of simplicity, description will be given of adjacent two terminals (hereinafter, an odd number output terminal is referred to as S1, and an even number output terminal is referred to as S2).

As shown in FIG. 9, a positive polarity grayscale voltage VPx (hereinafter, referred to as grayscale voltage VPx) and a negative polarity grayscale voltage VNx (hereinafter, referred to as grayscale voltage VNx) are inputted into terminals I1 and I2 of the amplifying circuit 5, respectively. The grayscale voltages VPx and VNx are grayscale voltages obtained by digital-to-analog converting video signals corresponding to two outputs from the DA converter 3.

The amplifying circuit 5 of FIG. 9 includes: a polarity switching part 10 that outputs the grayscale voltages VPx and VNx in turn from the terminals I1 and I2 while alternating the polarities of the grayscale voltages VPx and VNx; a voltage follower 8 that amplifies the driving performance of the grayscale voltages VPx and VNx received from the polarity switching part 10 and outputs the thus amplified grayscale voltages; and an output switching part 9 that outputs the grayscale voltages VPx and VNx in turn from the output terminals S1 and S2 of the amplifying circuit 5 while alternating the polarities for every one horizontal period (the output switching part is not shown in JP-A 2000-221927 (FIG. 2).)

In the polarity switching part 10, switches SW1, SW2, SW3, and SW4 are controlled by a polarity inverting signal POL and a strobe signal STB. The switches SW1 and SW4 and the switches SW2 and SW3 complementarily operate.

The voltage follower 8 includes a first amplifying part 81 and a second amplifying part 82. The switches SW1 and SW2 are connected to an input of the first amplifying part 81, and the switches SW3 and SW4 are connected to an input of the second amplifying part 82, respectively.

The output switching part 9 is connected to outputs of the first amplifying part 81 and the second amplifying part 82, and is controlled according to the strobe signal STB to be ON during driving of the liquid crystal panel and to be OFF during the charge recovery.

Next, operation of the amplifying circuit will be described. In one horizontal period, the grayscale voltages VPx and VNx from the DA converter 3 are respectively outputted to the switches SW1 and SW3 and switches SW2 and SW4 of the polarity switching part 10. Here, the polarity switching part 10 is controlled according to the polarity inverting signal POL and the strobe signal STB as shown in a timing chart of FIG. 10. For example, in response to the polarity inverting signal POL=“H” and the strobe signal STB=“H,” the switches SW1 and SW4 are switched from OFF to ON, and the switches SW2 and SW3 are switched from ON to OFF. As a result, the grayscale voltages VPx and VNx are inputted from the DA converter 3 into the first amplifying part 81 and the second amplifying part 82 of the voltage follower 8, respectively. Then, impedance conversion of the grayscale voltages VPx and VNx are performed in the first amplifying part 81 and the second amplifying part 82, respectively. Simultaneously, synchronizing with the strobe signal STB=“L,” output switches SW5 and SW6 turn ON. Thereby, the grayscale voltage VPx is outputted from the first amplifying part 81 to the output terminal S1, and the grayscale voltage VNx is outputted from the second amplifying part 82 to the output terminal S2.

In the next one horizontal period, the grayscale voltages VPx and VNx from the DA converter 3 are respectively inputted into the switches SW1 and SW3 and switches SW2 and SW4 of the polarity switching part 10. Here, as shown by the timing chart of FIG. 10, the polarity switching part 10 is controlled in response to the polarity inverting signal POL=“L” and the strobe signal STB=“H,” so that the switches SW2 and SW3 are switched from OFF to ON and the switches SW1 and SW4 are switched from ON to OFF. As a result, the grayscale voltages VNx and VPx are inputted from the DA converter 3 into the first amplifying part 81 and the second amplifying part 82 of the voltage follower 8, respectively. Then, impedance conversion of the grayscale voltages VNx and VPx are performed in the first amplifying part 81 and the second amplifying part 82, respectively. Simultaneously, synchronizing with the strobe signal STB=“L,” the output switches SW5 and SW6 turn on. Thereby, the grayscale voltage VNx is outputted from the first amplifying part 81 to the output terminal S1, and the grayscale voltage VPx is outputted from the second amplifying part 82 to the output terminal S2.

Afterwards, in a similar manner, the amplifying circuit 5 alternately outputs the grayscale voltages VPx and VNx corresponding to logic using external signals (the polarity inverting signal POL and strobe signal STB) for every one horizontal period so that the polarities at the output terminals S1 and S2 would be alternated.

In essence, in a configuration of JP-A 2000-221927 (FIG. 2), the grayscale voltages VPx and VNx of the DA converter 3 are switched for every one horizontal period to be outputted to the first amplifying part 81 and second amplifying part 82. Then, after the impedance conversion of the grayscale voltages VPx and VNx in the first amplifying part 81 and second amplifying part 82, the liquid crystal panel is driven through the output switching part 9.

Next, an amplifying circuit 5 of Japanese Patent Application Publication No. Hei 11-249623 (FIG. 7) that has a configuration different from that in JP-A 2000-221927 (FIG. 2) will be described. FIG. 11 is a schematic view of the amplifying circuit 5 in Japanese Patent Application Publication No. Hei 11-249623 (JP-A 11-249623, below) (FIG. 7).

The amplifying circuit 5 of JP-A 11-249623 (FIG. 7) includes a voltage follower 8 and a polarity switching and output switching part 11.

The voltage follower 8 includes a first amplifying part 81 and a second amplifying part 82. A grayscale voltage VPx from a DA converter 3 is inputted into a noninverting input terminal of the first amplifying part 81 through a terminal I1, and an output of the first amplifying part 81 is fed back to an inverting input terminal thereof, thereby forming a voltage follower. A grayscale voltage VNx from the DA converter 3 is inputted into a noninverting input terminal of the second amplifying part 82 through a terminal I2, and an output of the second amplifying part 82 is fed back to an inverting input terminal thereof, thereby forming a voltage follower.

The polarity switching and output switching part 11 includes switches SW7, SW8, SW9, and SW10. The switches SW7 and SW9 are connected to an output OUT1 of the first amplifying part 81, and the switches SW8 and SW10 are connected to an output OUT2 of the second amplifying part 82, respectively. The switches are controlled according to logic of a polarity inverting signal POL and a strobe signal STB. The switches SW7 and SW10 and the switches SW8 and SW9 are configured to be complementarily operated ON and OFF.

Next, operation of the amplifying circuit 5 of JP-A 11-249623 (FIG. 7) will be described. The grayscale voltage VPx from the DA converter 3 is inputted into the noninverting input terminal of the first amplifying part 81 through the terminal I1, and the grayscale voltage VNx is inputted into the noninverting input terminal of the second amplifying part 82 through the terminal I2. Since the amplifying circuit 5 has a configuration of the voltage follower, impedance conversion of the grayscale voltages VPx and VNx are performed in the first amplifying part 81 and the second amplifying part 82, respectively. The output OUT1 of the first amplifying part 81 is connected to the switches SW7 and SW9 of the polarity switching and output switching part 11, and the output OUT2 of the second amplifying part 82 is connected to the switches SW8 and SW10 of the polarity switching and output switching part 11.

The polarity switching and output switching part 11 is controlled according to logic of the polarity inverting signal POL and the strobe signal STB. A polarity inverting signal POL′ is generated from the polarity inverting signal POL, and a STB bar that is an inverted strobe signal STB is further generated as shown in a timing chart of FIG. 12. An ON or OFF state of the switches SW7 and SW10 is decided by taking an inversion (NAND) of a logical product of the POL′ and the STB bar, generating a bar of a value of the switches SW7 and SW10, and taking an inversion thereof.

Next, an ON or OFF state of the switches SW8 and SW9 is decided by taking an inversion (NOR) of a logical sum of the POL′ and the strobe signal STB.

As a result, the amplifying circuit 5 can alternately output the grayscale voltages VPx and VNx for every one horizontal period so that the polarities at S1 and S2 would be alternate.

Besides, Japanese Patent Application Publication No. 2002-175052 (JP-A 2002-175052) (FIG. 6), whose object and configuration are completely different from those of the present invention, discloses switching means (47 and 48 of FIG. 6 in JP-A2002-175052) equivalent to the polarity switching and output switching part 11 of JP-A 11-249623 (FIG. 7).

Moreover, Japanese Patent Application Publication No. 2000-98331 (JP-A2000-98331) discloses a technique in which using a segment display method completely different from the method of the present invention, a voltage selected from a reference power supply is inputted into two amplifying parts and an output of an amplifying part is switched.

As mentioned above, in JP-A 11-249623 (FIG. 7), JP-A 2002-175052 (FIG. 6), and JP-A 2000-98331, the impedance conversion of the grayscale voltages VPx and VNx from the DA converter 3 is performed directly in the first amplifying part 81 and the second amplifying part 82, respectively. Then, the polarity switching and output switching part 11, which is arranged between the outputs OUT1 and OUT2 of the first amplifying part 81 and the second amplifying part 82, and the output terminals S1 and S2 of the amplifying circuit 5, is controlled according to the external signals so that the polarities at the outputs terminals S1 and S2 would be alternated.

In JP-A2000-221927 (FIG. 2), since the polarity switching part 10 is provided in a preceding stage of the voltage follower 8, the input voltages of the first amplifying part 81 and the second amplifying part 82 have a wide range from the grayscale voltage VPx to the grayscale voltage VNx. For this reason, the amplifying circuit 5 has to amplify a wide range of operating power supply voltage with high accuracy, and thus needs to be configured to have the Rail-to-Rail property. For example, it is necessary to have a structure in which two differential pairs of a Pch transistor and an Nch transistor are combined, as an input stage of the amplifying circuit 5. As a result, such a complicated circuit configuration prevents reduction of the area of the amplifying circuit 5, and additionally, prevents reduction in power consumption.

In JP-A 11-249623 (FIG. 7), the amplifying circuit 5 has only to have the first amplifying part 81 including a differential pair of N channel MOS transistors that amplify the grayscale voltage VPx and the second amplifying part 82 including a differential pair of P channel MOS transistors that amplify the grayscale voltage VNx, and does not need to be configured to obtain the Rail-to-Rail property. Accordingly, the circuit can be formed to have an area smaller than that in JP-A 2000-221927 (FIG. 2), and can achieve reduction in power consumption.

However, the number of pixels has sharply been increased with enlargement of the screen size of the liquid crystal panel in recent years, and thus a load on the liquid crystal panel side tends to increase, when compared to the amplifying circuit 5 side. Additionally, with widespread use of image data having higher image quality, high-speed driving has become necessary. For this reason, it has become necessary to minimize voltage reduction of the output switch, i.e., to lower resistance value during operation. In JP-A 11-249623 (FIG. 7), however, the outputs from the amplifying part are switched by the polarity switching and output switching part 11, and the resultant voltages are applied to the liquid crystal panel. In this configuration, the amplifying circuit 5 needs to include the four switches SW7, SW8, SW9 and SW10, and one of the four switches SW7, SW8, SW9 and SW10 is connected in series between the amplifying circuit 5 and the output terminal S. Accordingly, large switching transistors have to be provided for the four switches SW7, SW8, SW9 and SW10 in order to lower the resistance, thus eliminating merits of JP-A 11-249623 (FIG. 7) in respect of the area (JP-A 2002-175052 (FIG. 6) and JP-A 2000-98331 are also similar).

Moreover, in JP-A 11-249623 (FIG. 7), as shown in FIG. 12, the logic needs to be built up from the polarity inverting signal POL and the strobe signal STB that are inputted from the outside, and therefore, control is complicated.

As mentioned above, in JP-A 2000-221927 (FIG. 2) and JP-A 11-249623 (FIG. 7), reduction in the area and in the power consumption cannot be achieved. Additionally, it is necessary to build up logic for switching, and therefore, control is complicated in JP-A 11-249623 (FIG. 7).

### SUMMARY OF THE INVENTION

An amplifying circuit according to the present invention includes: a first input stage amplifying part that receives a first input signal only at a transistor differential pair of a first conductivity type; a second input stage amplifying part that receives a second input signal different from the first input signal only at a transistor differential pair of a second conductivity type; first and second output stage amplifying parts; and a switching circuit that switches connections of the first input stage amplifying part and the second input stage amplifying part, with the first and second output stage amplifying parts, on the basis of external control signals.

An amplifying circuit according to the present invention is an amplifying circuit that applies a voltage in a range from a first supply voltage to a second supply voltage higher than the first supply voltage, the amplifying circuit including: a first input stage amplifying part consisting of a transistor differential pair of a first conductivity type; a second input stage amplifying part consisting of a transistor differential pair of a second conductivity type; first and second output stage amplifying parts; and a switching circuit that switches a connection of each of the first input stage amplifying part and the second input stage amplifying part, between the first and second output stage amplifying parts, on the basis of external control signals, wherein the first input stage amplifying part performs amplifying operation on a voltage if the voltage is approximately in a range from the second supply voltage, to a voltage obtained by adding the first supply voltage to a threshold voltage of a transistor that forms the transistor differential pair of the first conductivity type, and does not perform the amplifying operation if the voltage is out of the range, and the second input stage amplifying part performs amplifying operation on a voltage if the voltage is approximately in a range from the first supply voltage, to a voltage obtained by subtracting the second supply voltage by a threshold voltage of a transistor that forms the transistor differential pair of the second conductivity type, and does not perform the amplifying operation if the voltage is out of the range.

An amplifying circuit according to the present invention includes: a plurality of first input stage amplifying parts each of which receives a first input signal only at a transistor differential pair of a first conductivity type; a plurality of second input stage amplifying parts each of which receives a second input signal different from the first input signal only at a transistor differential pair of a second conductivity type; a plurality of first and second output stage amplifying parts; and a switching circuit that switches connection of each of the plurality of first input stage amplifying parts and the plurality of second input stage amplifying parts, with the plurality of first and second output stage amplifying parts, on the basis of external control signals.

An amplifying circuit according to the present invention is an amplifying circuit that applies a voltage in a range from a first supply voltage to a second supply voltage higher than the first supply voltage, the amplifying circuit including: a plurality of first input stage amplifying parts each consisting of a transistor differential pair of a first conductivity type; a plurality of second input stage amplifying parts each consisting of a transistor differential pair of a second conductivity type; a plurality of first and second output stage amplifying parts; and a switching circuit that switches a connection of each of the plurality of first input stage amplifying parts and the plurality of second input stage amplifying parts, between the plurality of first and second output stage amplifying parts, on the basis of external control signals, wherein the plurality of first input stage amplifying parts each perform amplifying operation on a voltage if the voltage is approximately in a range from the second supply voltage, to a voltage obtained by adding the first supply voltage to a threshold voltage of a transistor that forms the transistor differential pair of the first conductivity type, and does not perform the amplifying operation if the voltage is out of the range, and the plurality of second input stage amplifying parts each perform amplifying operation on a voltage if the voltage is approximately in a range from the first supply voltage, to a voltage obtained by subtracting the second supply voltage by a threshold voltage of a transistor that forms the transistor differential pair of the second conductivity type, and does not perform the amplifying operation if the voltage is out of the range.

A display unit on which an amplifying circuit according to the present invention is mounted is provided, the amplifying circuit including: a first input stage amplifying part that receives a first input signal only at a transistor differential pair of a first conductivity type; a second input stage amplifying part that receives a second input signal different from the first input signal only at a transistor differential pair of a second conductivity type; first and second output stage amplifying parts; and a switching circuit that switches connections of the first input stage amplifying part and the second input stage amplifying part, with the first and second output stage amplifying parts, on the basis of external control signals.

A display unit on which an amplifying circuit according to the present invention is mounted is provided, the amplifying circuit applying a voltage in a range from a first supply voltage to a second supply voltage higher than the first supply voltage, the amplifying circuit including: a first input stage amplifying part consisting of a transistor differential pair of a first conductivity type; a second input stage amplifying part consisting of a transistor differential pair of a second conductivity type; first and second output stage amplifying parts; and a switching circuit that switches a connection of each of the first input stage amplifying part and the second input stage amplifying part, between the first and second output stage amplifying parts, on the basis of external control signals, wherein the first input stage amplifying part performs amplifying operation on a voltage if the voltage is approximately in a range from the second supply voltage, to a voltage obtained by adding the first supply voltage to a threshold voltage of a transistor that forms the transistor differential pair of the first conductivity type, and does not perform the amplifying operations if the voltage is out of the range, and the second input stage amplifying part performs amplifying operation on a voltage if the voltage is approximately in a range from the first supply voltage, to a voltage obtained by subtracting the second supply voltage by a threshold voltage of a transistor that forms the transistor differential pair of the second conductivity type, and does not perform the amplifying operation if the voltage is out of the range.

With the amplifying circuit 5 and a display unit (for example, liquid crystal display) according to the present invention, reduction in the area and in the power consumption can be achieved without building up complicated logic while maintaining properties thereof, as compared with the existing amplifying circuit 5 and display unit.

### BRIEF DESCRIPTION OF THE DRAWINGS

FIG. 1 is a block diagram of an amplifying circuit according to Embodiment 1 of the present invention;

FIG. 2 is a timing chart of the amplifying circuit according to Embodiment 1 of the present invention;

FIG. 3 is a detailed circuit diagram of the amplifying circuit according to Embodiment 1 of the present invention;

FIG. 4 is another circuit diagram of an output stage amplifying part of an amplifying part according to an embodiment of the present invention;

FIG. 5 is further another circuit diagram of an output stage amplifying part of an amplifying part according to an embodiment of the present invention;

FIG. 6 is a block diagram of an amplifying circuit according to Embodiment 2 of the present invention;

FIG. 7 is a block diagram of an amplifying circuit according to Embodiment 3 of the present invention;

FIG. 8 is a schematic view of a common liquid crystal display;

FIG. 9 is a block diagram of an amplifying circuit of the conventional art 1;

FIG. 10 is a timing chart of the amplifying circuit of the conventional art 1;

FIG. 11 is a block diagram of an amplifying circuit of the conventional art 2; and

FIG. 12 is a timing chart of the amplifying circuit of the conventional art 2.

### DESCRIPTION OF THE PREFERRED EMBODIMENTS

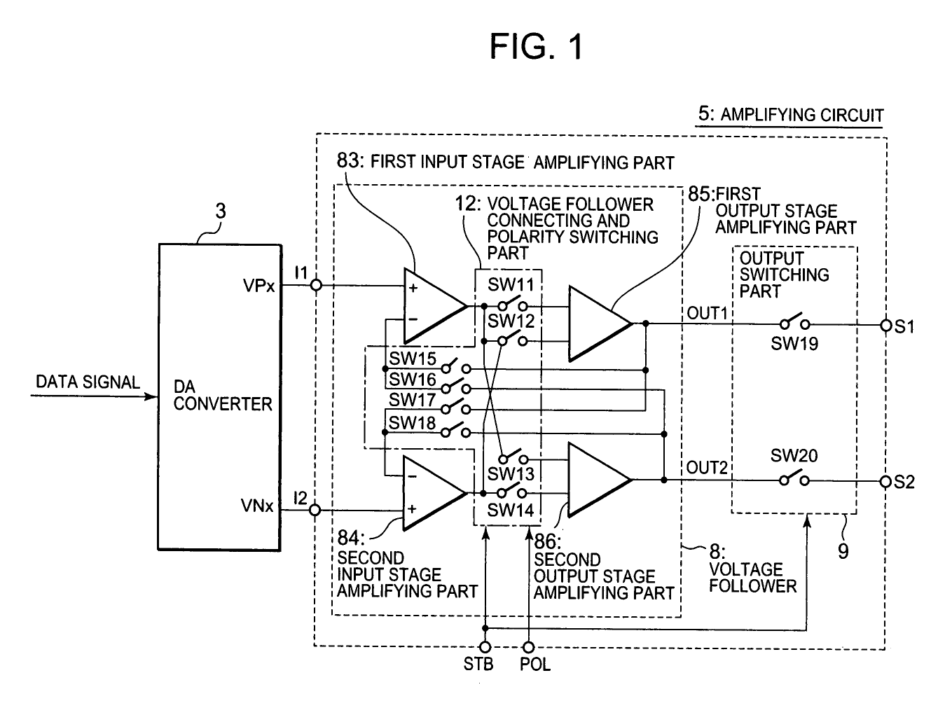

FIG. 1 is a block diagram of the present invention. An amplifying circuit 5 according to the present invention includes a first input stage amplifying part 83, a second input stage amplifying part 84, a voltage follower connecting and polarity switching part 12, a voltage follower 8 consisting of a first output stage amplifying part 85 and a second output stage amplifying part 86, and an output switching part 9. However, in apparatuses in which an output of a liquid crystal display drive circuit, i.e., an output of the amplifying circuit 5 does not need to be set to high impedance such as a case where charge recovery is not performed, the output switching part 9 is unnecessary, and therefore, it is possible to eliminate the output switching part 9. In this case, the voltage follower 8 becomes equivalent to the amplifying circuit 5.

Since in the first input stage amplifying part 83 of the voltage follower 8, a grayscale voltage VPx inputted into an input terminal I1 is limited to approximately an upper half of a voltage ranging from a lowest power supply voltage VSS (also referred to as a lower limit of negative voltage or a first power supply voltage) to a highest power supply voltage VDD (also referred to as an upper limit of positive voltage or a second power supply voltage), it is not necessary to input and output a voltage close to the lowest power supply voltage VSS. When a threshold voltage of an N channel MOS transistor that forms an N channel differential pair is defined as VTN, since the N channel differential pair inputs and outputs a voltage in a range approximately from (VSS+VTN) to the highest power supply voltage VDD, the first input stage amplifying part 83 can be formed of only the N channel MOS differential pair.

Similarly, since in the second input stage amplifying part 84 of the voltage follower 8, a grayscale voltage VNx inputted into an input terminal I2 is limited to approximately a lower half of a voltage ranging from the lowest power supply voltage VSS (lower limit of negative voltage) to the highest power supply voltage VDD (upper limit of positive voltage), it is not necessary to input and output a voltage close to the highest power supply voltage VDD. When a threshold voltage of a P channel MOS transistor that forms a P channel differential pair is defined as VTP, since the P channel differential pair inputs and outputs a voltage in a range approximately from the lowest power supply voltage VSS to (VDD−VTP), the second input stage amplifying part 84 can be formed of only the P channel MOS differential pair.

The voltage follower connecting and polarity switching part 12 of the voltage follower 8 is a circuit that switches connection of I/O among the first input stage amplifying part 83 and second input stage amplifying part 84 and the first output stage amplifying part 85 and second output stage amplifying part 86. The voltage follower connecting and polarity switching part 12 consists of multiple switches SW11, SW12, SW13, SW14, SW15, SW 16, SW17, and SW18. Additionally, an ON or OFF state of these switches is controlled by a polarity inverting signal POL and a strobe signal STB that are signals from the outside. The switch SW11, SW14, SW15, and SW18, and the switch SW12, SW13, SW16, and SW17 complementarily switch ON and OFF.

The first output stage amplifying part 85 of the voltage follower 8 receives an output from the first input stage amplifying part 83 or the second input stage amplifying part 84 through the switch SW11 or SW12 of the voltage follower connecting and polarity switching part 12, and outputs a voltage corresponding to a video signal from an output terminal S1 to a TFT 6 of a liquid crystal display panel when a switch SW19 of the output switching part 9 is ON. Similarly, the second output stage amplifying part 86 of the voltage follower 8 receives an output from the first input stage amplifying part 83 or the second input stage amplifying part 84 through the switch SW13 or SW14 of the voltage follower connecting and polarity switching part 12, and outputs a voltage corresponding to a video signal from an output terminal S2 to the TFT 6 of the liquid crystal display panel when a switch SW20 of the output switching part 9 is ON.

An ON or OFF state of the output switching part 9 is controlled by the strobe signal STB that is a signal from the outside. The output switching part 9 is configured to be ON when driving the liquid crystal panel, and to be OFF during charge recovery.

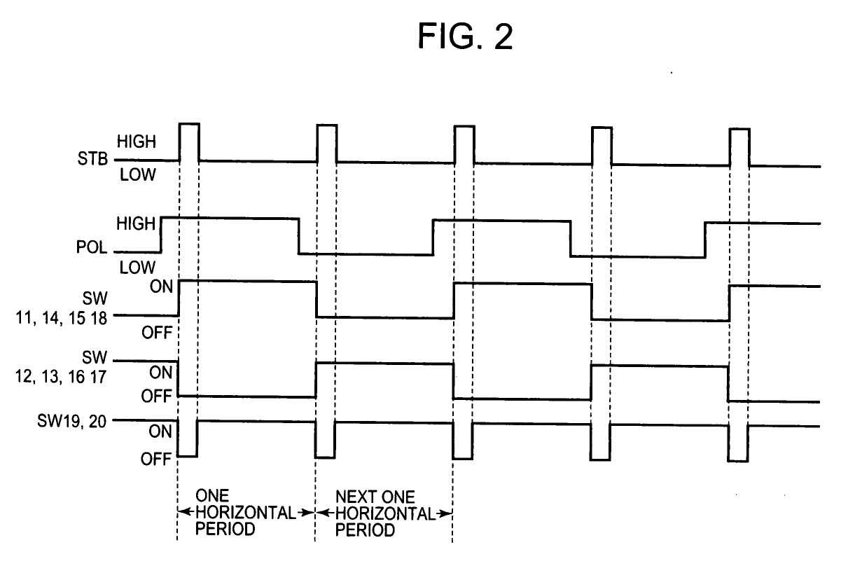

Next, operation of the present invention will be described using the block diagram of the amplifying circuit 5 of FIG. 1 and a timing diagram of FIG. 2.

In one horizontal period, the grayscale voltage VPx from the DA converter 3 is inputted into an noninverting input terminal of the first input stage amplifying part 83 through the input terminal I1 of the first input stage amplifying part 83, and the grayscale voltage VNx is inputted into an noninverting input terminal of the second input stage amplifying part 84 through the input terminal I2 of the first input stage amplifying part 83, respectively.

The output terminal of the first input stage amplifying part 83 is connected to the switches SW11 and SW13 of the voltage follower connecting and polarity switching part 12, and the inverting input terminal of the first input stage amplifying part 83 is connected to the switches SW15 and SW16. The output terminal of the second input stage amplifying part 84 is connected to the switches SW12 and SW14 of the voltage follower connecting and polarity switching part 12, and the inverting input terminal of the second input stage amplifying part 84 is connected to the switches SW17 and SW18.

Here, the voltage follower connecting and polarity switching part 12 is controlled by the polarity inverting signal POL and the strobe signal STB as shown by the timing chart of FIG. 2. For example, assume that the switches SW11, SW14, SW15, and SW18 are switched from OFF to ON, and the switches SW 12, SW13, SW16, and SW17 are switched from ON to OFF by the polarity inverting signal POL=“H” and the strobe signal STB=“H”. As a result, the output from the first input stage amplifying part 83 is inputted into the first output stage amplifying part 85, and then an output OUT1 from the first output stage amplifying part 85 is inputted into the noninverting input terminal of the first input stage amplifying part 83. In essence, the first input stage amplifying part 83 and the first output stage amplifying part 85 form one amplifying unit of the voltage follower configuration. Similarly, the second input stage amplifying part 84 and the second output stage amplifying part 86 form one amplifying unit of the voltage follower configuration.

The switches SW19 and SW20 are turned ON by the strobe signal STB=“L,” and output voltages, each corresponding to a video signal, of the first output stage amplifying part 85 and the second output stage amplifying part 86 are outputted to the TFT 6 of the liquid crystal panel from the output terminals S1 and S2.

In the next one horizontal period, the grayscale voltage VPx from the DA converter 3 is inputted into the noninverting input terminal of the first input stage amplifying part 83 through the input terminal I1 of the first input stage amplifying part 83. The grayscale voltage VNx is inputted into the noninverting input terminal of the second input stage amplifying part 84 through the input terminal I2 of the second input stage amplifying part 84.

The switches SW12, SW13, SW16, and SW17 are switched from OFF to ON, and the switches SW11, SW14, SW15, and SW18 are switched from ON to OFF by the polarity inverting signal POL=“L” and the strobe signal STB=“H”. As a result, the output of the first input stage amplifying part 83 is inputted into the second output stage amplifying part 86, and then an output OUT2 of the second output stage amplifying part 86 is connected to the noninverting input terminal of the first input stage amplifying part 83. In essence, the first input stage amplifying part 83 and the second output stage amplifying part 86 from one amplifying unit of the voltage follower configuration. Additionally, the second input stage amplifying part 84 and the first output stage amplifying part 85 form one amplifying unit of the voltage follower configuration. The switches SW19 and SW20 are turned ON by the strobe signal STB=“L,” and the output voltages, each corresponding to a video signal, of the first output stage amplifying part 85 and the second output stage amplifying part 86 are outputted to the TFT 6 of the liquid crystal panel from the output terminals S1 and S2.

Afterwards, in a similar manner, the amplifying circuit 5 alternately outputs the grayscale voltages VPx and VNx corresponding to logic of the video signal for every one horizontal period so that the polarities at S1 and S2 would be alternated.

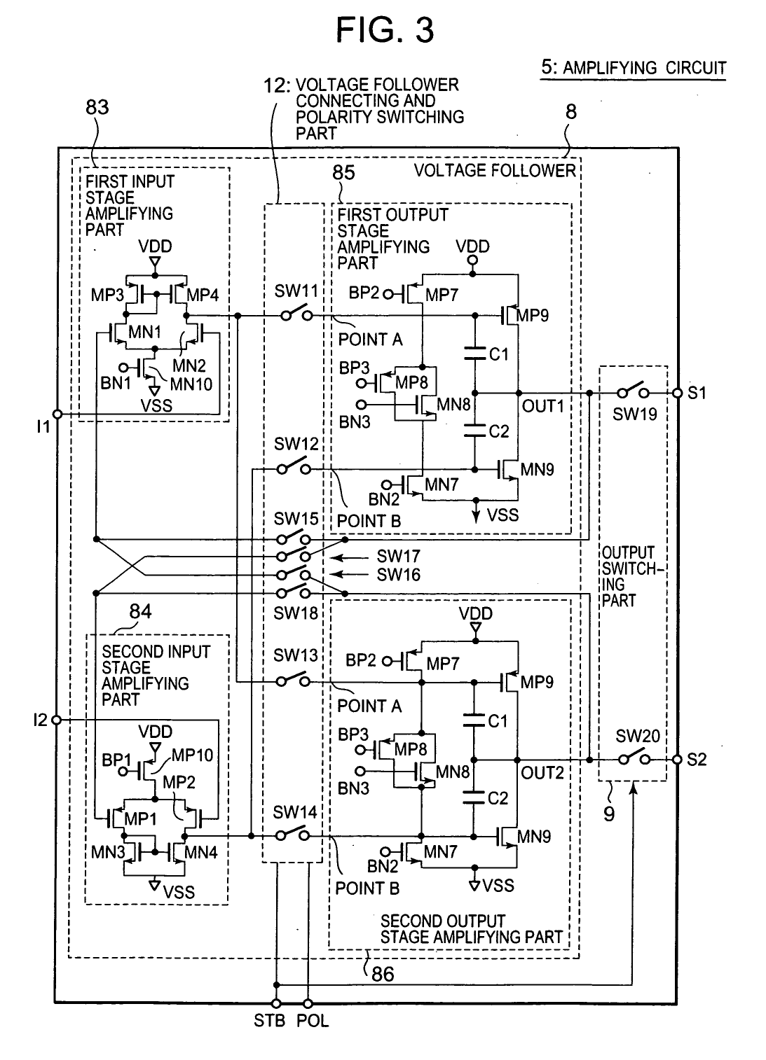

Next, the configuration and operation of the amplifying circuit 5 will be described in more detail using a detailed circuit diagram thereof shown in FIG. 3.

First, assume that in one horizontal period, in the voltage follower connecting and polarity switching part 12, the switches SW11, SW14, SW15, and SW18 are switched from OFF to ON, and the switches SW12, SW13, SW16, and SW17 are switched from ON to OFF by the polarity inverting signal POL=“H” and the strobe signal STB=“H”. Further, the switches SW19 and SW20 are ON during the strobe signal STB=“L.”

In the first input stage amplifying part 83, sources of N channel MOS transistors MN1 and MN2 are connected in common to form a differential pair. An N channel MOS transistor MN10 is connected between the differential pair and a lowest power supply voltage VSS. In the N channel MOS transistor MN10, a source thereof is connected to the lowest power supply voltage VSS, a drain thereof is connected to the sources of the N channel MOS transistors MN1 and MN2 connected in common, and a gate thereof is connected to a constant voltage source terminal BN1 to act as a constant current source. In P channel MOS transistors MP3 and MP4, sources and gates thereof are respectively connected in common, the sources are connected to a highest power supply voltage VDD, and the gates are connected to the drain of the P channel MOS transistor MP3 and the drain of the N channel MOS transistor MN1. The drain of the P channel MOS transistor MP4 is connected to the drain of the N channel MOS transistor MN2.

Since the switch SW11 is ON and the switch SW13 is OFF, the drain of the N channel MOS transistor MN2 in the first input stage amplifying part 83 is connected to a connection node, point A, for connecting to a drain of a P channel MOS transistor MP7 and a source of a P channel MOS transistor MP8 in the first output stage amplifying part 85.

In the P channel MOS transistor MP7, a source thereof is connected to a highest power supply voltage VDD, a drain thereof is connected to the point A, and a gate thereof is connected to a constant voltage source terminal BP2 to act as a constant current source. In an N channel MOS transistor MN7, a source thereof is connected to a lowest power supply voltage VSS, a drain thereof is connected to a point B, and a gate thereof is connected to a constant voltage source terminal BN2 to act as a constant current source. In the P channel MOS transistor MP8, a gate thereof is connected to a constant voltage source terminal BP3, a source thereof is connected to the drain of the P channel MOS transistor MP7, and a drain thereof is connected to the drain of the N channel MOS transistor MN7. In an N channel MOS transistor MN8, a gate thereof is connected to a constant voltage source terminal BN3, a source thereof is connected to the drain of the N channel MOS transistor MN7, and a drain thereof is connected to the drain of the P channel MOS transistor MP7. The P channel MOS transistor MP8 and the N channel MOS transistor MN8 each act as a floating current source. This floating current source is an AB class output stage controlled by bias voltages from the constant voltage source terminals BP3 and BN3, the N channel MOS transistor MN8 and the P channel MOS transistor MP8. A P channel MOS transistor MP9 is an output transistor whose source is connected to the highest power supply voltage VDD, whose gate is connected to the source of the P channel MOS transistor MP8, and whose drain is connected to the output terminal OUT1. An N channel MOS transistor MN9 is an output transistor whose source is connected to the lowest power supply voltage VSS, whose gate is connected to the source of the N channel MOS transistor MN8, and whose drain is connected to the output terminal OUT1.

One end of a phase compensation capacitor C1 is connected to the point A, and the other end thereof is connected to the output terminal OUT1. One end of a phase compensation capacitor C2 is connected to the point B, and the other end thereof is connected to the output terminal OUT1.

In order to achieve a Rail-to-Rail output, an AB class drain output is configured. The idling current of this AB class configuration is determined by the floating current sources (MP8, MN8), the constant voltage source terminals BN3 and BP3, the P channel MOS transistor MP9, and the N channel MOS transistor MN9.

Since the switch SW15 is ON and the switch SW17 is OFF, the output terminal OUT1 is connected to the gate of the N channel MOS transistor MN1 that is an inverting input of the first input stage amplifying part 83 to form a feedback circuit, thus providing a voltage follower configuration. The AB class amplifying circuit having the voltage follower configuration obtains high input impedance and low output impedance. Impedance conversion of the grayscale voltage VPx is performed, the grayscale voltage VPx being received from the input terminal I1 that is connected to the gate of the N channel MOS transistor MN2, and the resultant voltage is outputted from the output terminal S1 through the switch SW19 (turned ON by the STB=“L”).

In the second input stage amplifying part 84, sources of P channel MOS transistors MP1 and MP2 are connected in common to form a differential pair. A P channel MOS transistor MP10 is connected between the differential pair and a highest power supply voltage VDD. In the P channel MOS transistor MP10, a source thereof is connected to the highest power supply voltage VDD, a drain thereof is connected to the sources of the P channel MOS transistors MP1 and MP2 connected in common, and a gate thereof is connected to a constant voltage source terminal BP1 to act as a constant current source. In N channel MOS transistors MN3 and MN4, sources and gates thereof are respectively connected in common, the sources are connected to a lowest power supply voltage VSS, and the gates are connected to the drain of the N channel MOS transistor MN3 and the drain of the P channel MOS transistor MP1. The drain of the N channel MOS transistor MN4 is connected to the drain of the P channel MOS transistor MP2. Since the switch SW14 of the voltage follower connecting and polarity switching part 12 is ON and the switch SW12 thereof is OFF, the drain of the P channel MOS transistor MP2 is connected to a connection node, point B, for connecting to a drain of an N channel MOS transistor MN7 and a source of an N channel MOS transistor MN8 in the second output stage amplifying part 86.

In a P channel MOS transistor MP7, a source thereof is connected to a highest power supply voltage VDD, a drain thereof is connected a point A, and a gate thereof is connected to a constant voltage source terminal BP2 to act as a constant current source. In the N channel MOS transistor MN7, a source thereof is connected to a lowest power supply voltage VSS, a drain thereof is connected to the point B, and a gate thereof is connected to a constant voltage source terminal BN2 to act as a constant current source.

In a P channel MOS transistor MP8, a gate thereof is connected to a constant voltage source terminal BP3, a source thereof is connected to the drain of the P channel MOS transistor MP7, and a drain thereof is connected to the drain of the N channel MOS transistor MN7. In the N channel MOS transistor MN8, a gate thereof is connected to a constant voltage source terminal BN3, a source thereof is connected to the drain of the N channel MOS transistor MN7, and a drain thereof is connected to the drain of the P channel MOS transistor MP7. The P channel MOS transistor MP8 and the N channel MOS transistor MN8 each act as a floating current source. This floating current source is an AB class output stage controlled by bias voltages from the constant voltage source terminals BP3 and BN3, the N channel MOS transistor MN8 and the P channel MOS transistor MP8.

A P channel MOS transistor MP9 is an output transistor whose source is connected to the highest power supply voltage VDD, whose gate is connected to the source of the P channel MOS transistor MP8, and whose drain is connected to the output terminal OUT2. An N channel MOS transistor MN9 is an output transistor whose source is connected to the lowest power supply voltage VSS, whose gate is connected to the source of the N channel MOS transistor MN8, and whose drain is connected to the output terminal OUT2.

One end of a phase compensation capacitor C1 is connected to the point A, and the other end thereof is connected to the output terminal OUT2. One end of a phase compensation capacitor C2 is connected to the point B, and the other end thereof is connected to the output terminal OUT2.

In order to achieve a Rail-to-Rail output, an AB class drain output is formed. The idling current of this AB class configuration is determined by the floating current sources (MP8, MN8), the constant voltage source terminals BN3 and BP3, the P channel MOS transistor MP9, and the N channel MOS transistor MN9.

Since the switch SW18 is ON and the switch SW16 is OFF, the output terminal OUT2 is connected to the gate of the P channel MOS transistor MP1 that is an inverting input of the second input stage amplifying part 84 to form a feedback circuit, thus providing a voltage follower configuration. The AB class amplifying circuit having the voltage follower configuration obtains high input impedance and low output impedance. Impedance conversion of the grayscale voltage VNx is performed, the grayscale voltage VNx being received from the input terminal I2 that is connected to the gate of the P channel MOS transistor MP2, and the resultant voltage is outputted from the output terminal S2 through the switch SW20 (turned ON by the STB=“L”).

In the next one horizontal period, assume that the switches SW12, SW13, SW16, and SW17 are switched from OFF to ON, and the switches SW11, SW14, SW15, and SW18 are switched from ON to OFF by the polarity inverting signal POL=“L” and the strobe signal STB=“H”. Further, the switches SW19 and SW20 are ON during the strobe signal STB=“L”.

Here, since the configuration of the first input stage amplifying part 83, the second input stage amplifying part 84, the first output stage amplifying part 85 and the second output stage amplifying part 86 is the same as the above description, detailed description thereof will be omitted.

When the switch SW13 is turned ON and the switch SW11 is turned OFF, the drain of the N channel MOS transistor MN2 in the first input stage amplifying part 83 is connected to the point A connecting to the drain of the P channel MOS transistor MP7 and the source of the P channel MOS transistor MP8 in the second output stage amplifying part 86.

Moreover, since the switch SW16 is ON and the switch SW18 is OFF, the output terminal OUT2 is connected to the gate of the N channel MOS transistor MN1 that is an inverting input of the first input stage amplifying part 83 to form a feedback circuit, thus providing a voltage follower configuration. The AB class amplifying circuit having the voltage follower configuration obtains high input impedance and low output impedance. The grayscale voltage VPx inputted into the input terminal I1 is outputted from the output terminal S2 through the switch SW20 (turned ON by the STB=“L”).

Since the switch SW12 is ON and the switch SW14 is OFF, the drain of the P channel MOS transistor MP2 of the second input stage amplifying part 84 is connected to the point B connecting to the drain of the N channel MOS transistor MN7 and the source of N channel MOS transistor MN8 in the first output stage amplifying part 85.

Moreover, since the switch SW17 is ON and the switch SW15 is OFF, the output terminal OUT1 is connected to the gate of the P channel MOS transistor MP1 that is an inverting input of the second input stage amplifying part 84 to form a feedback circuit, thus providing a voltage follower configuration. The AB class amplifying circuit having the voltage follower configuration obtains high input impedance and low output impedance. The grayscale voltage VNx inputted into the input terminal I2 is outputted from the output terminal S1 through the switch SW19 (turned ON by the STB=“L”).

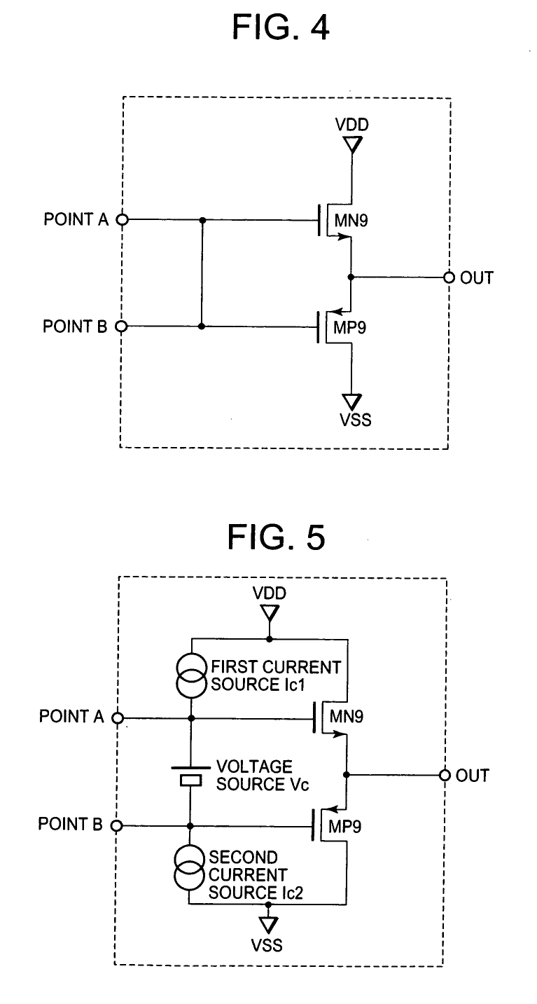

FIG. 4 shows another circuit diagram of the output stage amplifying part according to Embodiment 1 of the present invention. What is different from Embodiment 1 of the present invention shown in FIG. 3 is only an output stage amplifying part, and other configuration of the first input stage amplifying part 83, the second input stage amplifying part 84, the voltage follower connecting and polarity switching part 12, and the output switching part 9 is basically the same. Specifically, in the configuration shown in FIG. 4, the first output stage amplifying part 85 and the second output stage amplifying part 86 of FIG. 3 are replaced with a first output stage amplifying part 85 and a second output stage amplifying part 86 of FIG. 4. In FIG. 4, since the first output stage amplifying part 85 and the second output stage amplifying part 86 have the same functional configuration, only one configuration is shown.

Since the switching of the voltage follower connecting and polarity switching part 12 in accordance with the polarity inverting signal POL and the strobe signal STB inputted from the outside are performed in the same manner as in the case of Embodiment 1 shown in FIG. 3, description will be omitted.

The output stage amplifying part includes an N channel MOS transistor MN9 with a source follower configuration and a P channel MOS transistor MP9 with a source follower configuration. Gates of both of the transistors MN9 and MP9 are connected in common to a point A and a point B that are input terminals of the input stage amplifying part (first input stage amplifying part 83 or second input stage amplifying part 84). Sources of both of the transistors MN9 and MP9 are connected in common to an output terminal OUT (OUT1 or OUT2) A drain of the N channel MOS transistor MN9 is connected to a highest power supply voltage VDD, and a drain of the P channel MOS transistor MP9 is connected to a lowest power supply voltage VSS. Since the output terminal OUT (OUT1 or OUT2) is connected to an inverting input terminal of the input stage amplifying part, a signal from the output terminal OUT (OUT1 or OUT2) is fed back to the inverting input terminal of the input stage amplifying part (first input stage amplifying part 83 or second input stage amplifying part 84). Thereby, the amplifying circuit 5 can perform a class B push-pull amplification.

FIG. 5 shows still another circuit diagram of an output stage amplifying part of the amplifying part according to Embodiment 1 of the present invention. The output stage amplifying part of the amplifying part also includes an N channel MOS transistor MN9 with a source follower configuration and a P channel MOS transistor MP9 with a source follower configuration, and further includes a first current source Ic1, a second current source Ic2, and a voltage source Vc.

In the output stage amplifying part of the amplifying part, since the first output stage amplifying part 85 and the second output stage amplifying part 86 also have basically the same configuration, only one configuration is shown.

Additionally, since the switching of the voltage follower connecting and polarity switching part 12 in accordance with the polarity inverting signal POL and the strobe signal STB inputted from the outside are performed in the same manner as in the case of Embodiment 1 shown in FIG. 3, description will be omitted.

The configuration will be described. The gate of the N channel MOS transistor MN9 is connected to one end of the first current source Ic1, an input terminal, point A, and one end of the voltage source Vc. The other end of first current source Ic1 is connected to a highest power supply voltage VDD. The gate of the P channel MOS transistor MP9 is connected to one end of the second current source Ic2, an input terminal, point B, and the other end of the voltage source Vc. The other end of the second current source Ic2 is connected to a lowest power supply voltage VSS. The sources of MN9 and MP9 are connected in common to an output terminal OUT (OUT1 or OUT2). The circuit illustrated in FIG. 3 may be used for the first current source Ic1, the second current source Ic2, and the voltage source Vc.

Since the output terminal OUT (OUT1 or OUT2) is connected to an inverting input terminal of the input stage amplifying part (first input stage amplifying part 83 or second input stage amplifying part 84), a signal from the output terminal OUT (OUT1 or OUT2) is fed back to the inverting input terminal of the input stage amplifying part (first input stage amplifying part 83 or second input stage amplifying part 84). Thereby, the amplifying circuit 5 can perform a class A or class AB push-pull amplification.

Since the output stage amplifying parts in the examples of FIGS. 4 and 5 include the N channel MOS transistor MN9 with the source follower configuration and the P channel MOS transistor MP9 with the source follower configuration, the phase compensation capacitor C1 and phase compensation capacitor C2 needed in the amplifying circuit 5 of FIG. 3 are unnecessary.

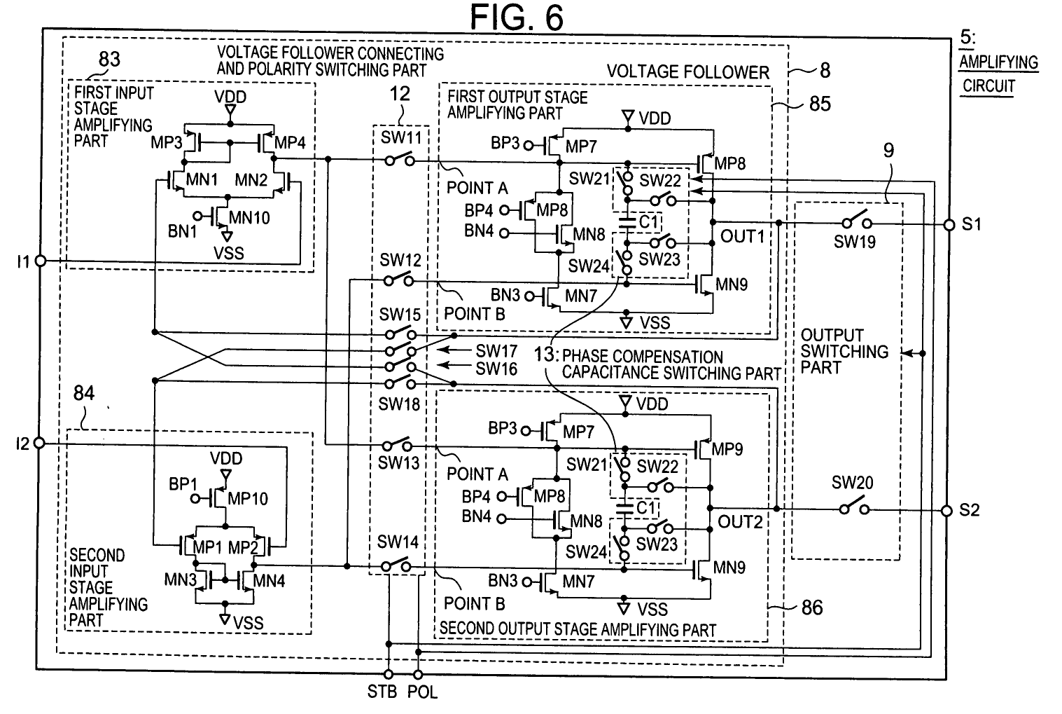

FIG. 6 shows a specific circuit diagram of an amplifying circuit 5 according to Embodiment 2 of the present invention. Configurations of the first input stage amplifying part 83, the second input stage amplifying part 84, the voltage follower connecting and polarity switching part 12, and the output switching part 9 are basically the same as Embodiment 1 of the present invention of FIG. 3. As compared with Embodiment 1 of the present invention of FIG. 3, the output stage amplifying part has a configuration in which a phase compensation capacitance switching part 13 consisting of switches SW21, SW22, SW23, and SW24 is added, and the phase compensation capacitor C2 is eliminated.

Next, operation of the amplifying circuit 5 according to Embodiment 2 will be described. However, the configurations of the first input stage amplifying part 83, the second input stage amplifying part 84, the voltage follower connecting and polarity switching part 12, and the output switching part 9 are the same as the amplifying circuit 5 according to Embodiment 1 of FIG. 3. Such being the case, operations in these portions are similar. Thus, detailed description thereof will be omitted, and only the phase compensation capacitance switching part 13 and a phase compensation capacitor C1 will be described.

A first output stage amplifying part 85 and a second output stage amplifying part 86 operate so that ON/OFF state of the switches in one output stage amplifying part may be opposite to the other output stage amplifying part. Specifically, the switches SW21 and SW23 of a phase compensation capacitance switching part 13 of the first output stage amplifying part 85 are switched from OFF to ON, and the switches SW22 and SW24 are switched from ON to OFF, while the switches SW21 and SW23 of a phase compensation capacitance switching part 13 of the second output stage amplifying part 86 are switched from ON to OFF, and the switches SW22 and SW24 are switched from OFF to ON, when a polarity inverting signal POL=“H” and a strobe signal STB=“H”. Alternatively, the switches SW21 and SW23 of the phase compensation capacitance switching part 13 of the first output stage amplifying part 85 are switched from ON to OFF, and the switches SW22 and SW24 are switched from OFF to ON, while the switches SW21 and SW23 of the phase compensation capacitance switching part 13 of the second output stage amplifying part 86 are switched from OFF to ON, and the switches SW22 and SW24 are switched from ON to OFF, when the polarity inverting signal POL=“L” and the strobe signal STB=“H”.

In one horizontal period, as described in Embodiment 1 of FIG. 3, impedance conversion of a grayscale voltage VPx received from an input terminal I1 is performed in the first output stage amplifying part 85 in accordance with the polarity inverting signal POL=“H” and the strobe signal STB=“H,” and the resultant voltage is outputted from an output terminal S1 through a switch S19. Here, since the switches SW21 and SW23 of the phase compensation capacitance switching part 13 are turned ON, the phase compensation capacitor C1 is connected between an output OUT1 and a point A. Similarly, impedance conversion of a grayscale voltage VNx received from an input terminal I2 is performed in the second output stage amplifying part 86, and the resultant voltage is outputted from an output terminal S2 through a switch SW20. Here, since the switches SW22 and SW24 of the phase compensation capacitance switching part 13 are turned ON, the phase compensation capacitor C1 is connected between an output OUT2 and a point B. Thereby, each phase compensation capacitor C1 in the first output stage amplifying part 85 and the second output stage amplifying part 86 functions as a phase compensation capacitor.

In the next one horizontal period, as described in Embodiment 1 of FIG. 3, impedance conversion of the grayscale voltage VNx received from the input terminal I2 is performed in the first output stage amplifying part 85 in accordance with the polarity inverting signal POL=“L” and the strobe signal STB=“H,” and the resultant voltage is outputted from the output terminal S1 through the switch SW19. Here, since the switches SW22 and SW24 of the phase compensation capacitance switching part 13 are turned ON, the phase compensation capacitor C1 is connected between the output OUT1 and the point B. Similarly, impedance conversion of the grayscale voltage VPx received from the input terminal I1 is performed in the second output stage amplifying part 86, and the resultant voltage is outputted from the output terminal S2 through the switch SW20. Here, since the switches SW21 and SW23 of the phase compensation capacitance switching part 13 are turned ON, the phase compensation capacitor C1 is connected between the output OUT2 and the point A. Thereby, each phase compensation capacitor C1 in the first output stage amplifying part 85 and the second output stage amplifying part 86 functions as a phase compensation capacitor.

As has been described above, in the amplifying circuit 5 according to Embodiment 2 of the present invention shown in FIG. 6, as compared with Embodiment 1 of the present invention in FIG. 3, by switching the switches at the time of outputting the grayscale voltage VPx and at the time of outputting the grayscale voltage VNx in accordance with the external signals (polarity inverting signal POL=“L” and strobe signal STB=“H”), each of the output terminals S1 and S2 uses one phase compensation capacitor C1 instead of using two phase compensation capacitors C1 and C2. Thus, even if the phase compensation capacitance switching part 13 consisting of a minimum transistor is added, further reduction in the area can be expected as compared to the case of using two phase compensation capacitors in Embodiment 1 of the present invention in FIG. 3.

The P channel MOS transistor MP9 and the N channel MOS transistor MN9 that are output transistors of the first output stage amplifying part 85 and the second output stage amplifying part 86 each have been described as a single transistor from FIG. 3 through FIG. 6. However, output transistors are not particularly limited thereto, and may be those that operate as a transistor of the same function as a whole such as transistors of a same conductivity type connected in parallel.

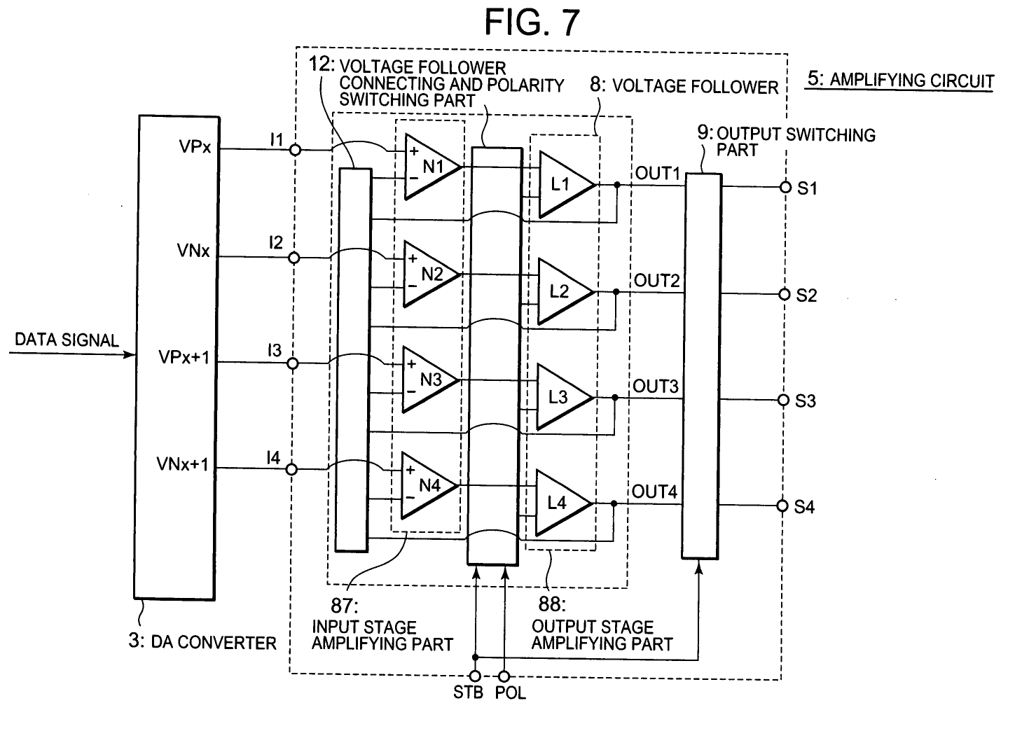

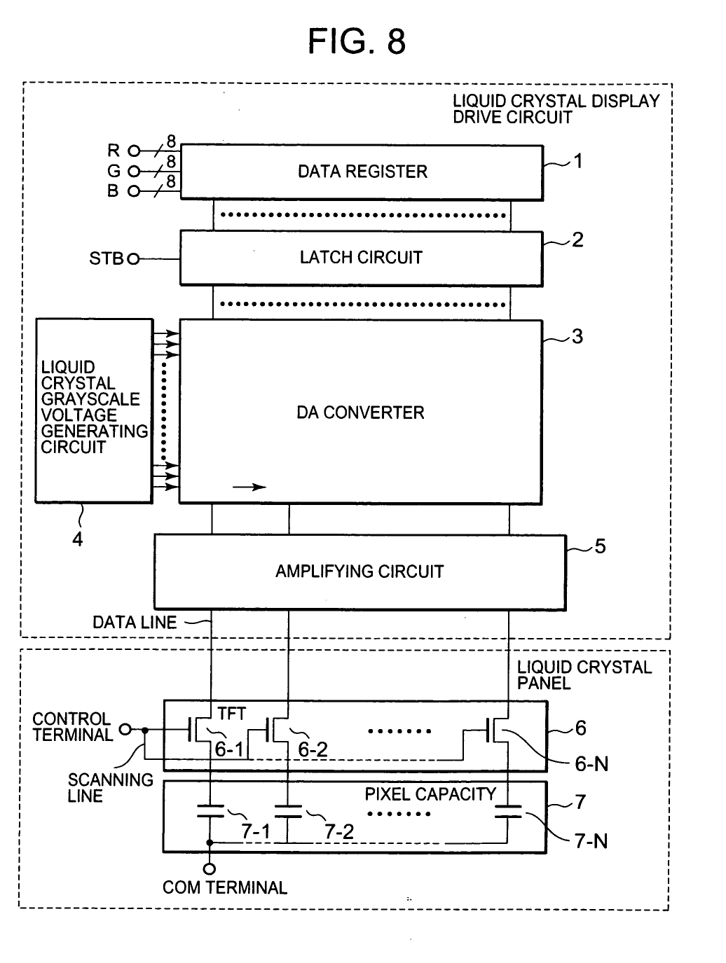

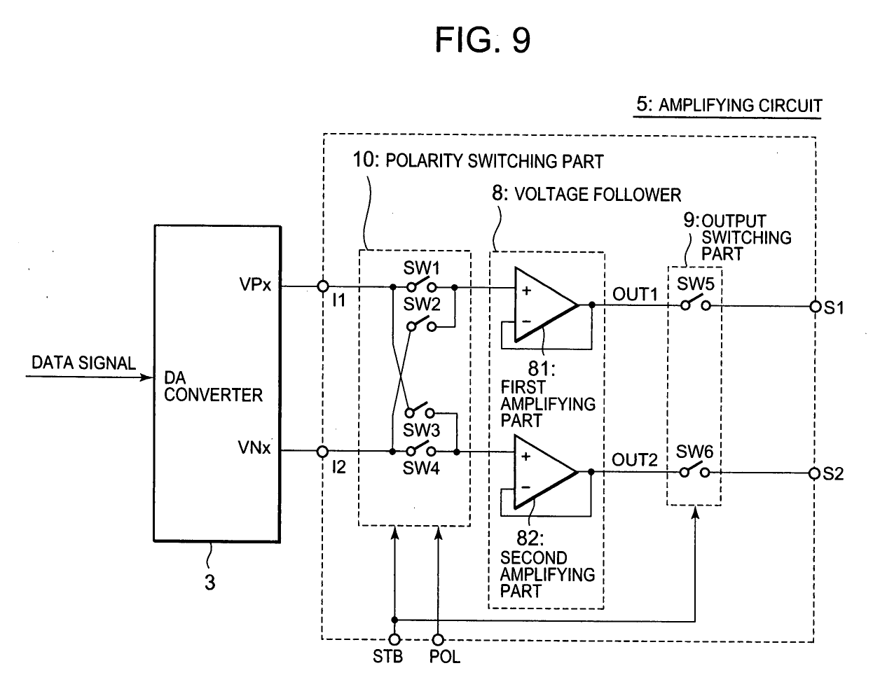

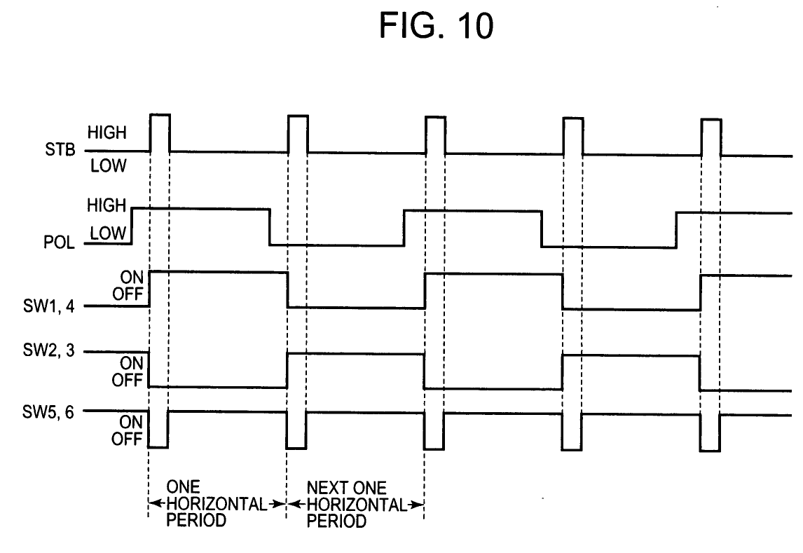

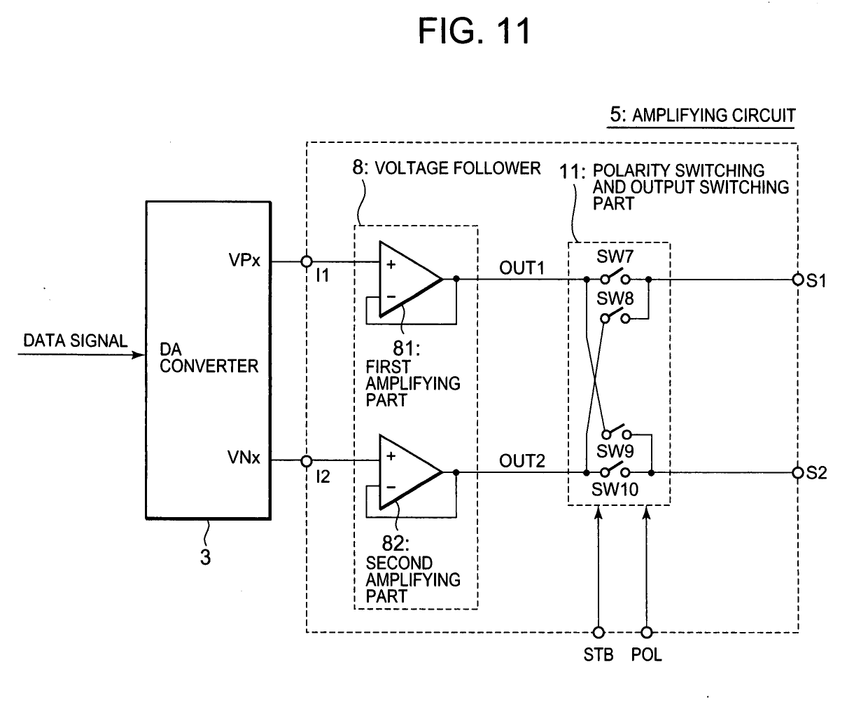

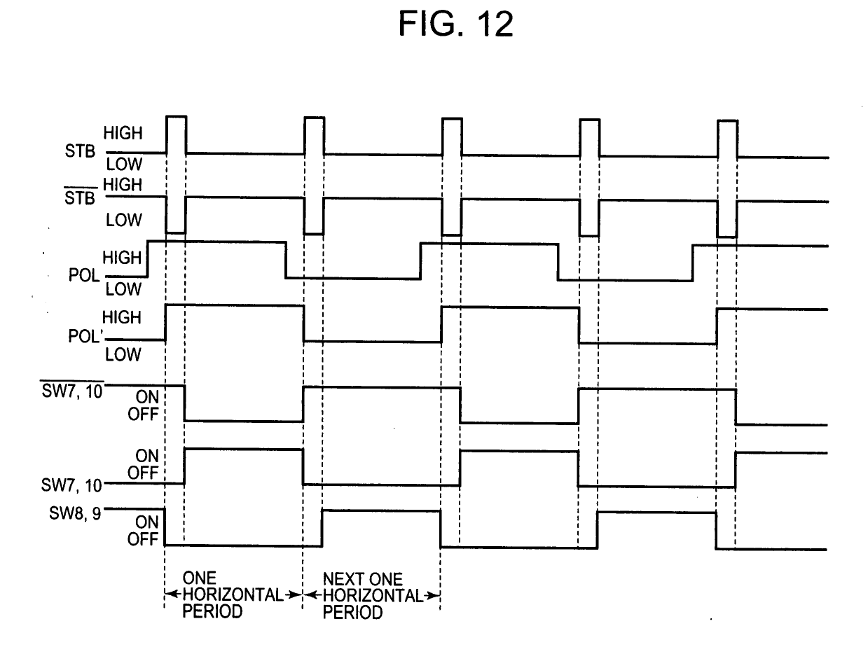

FIG. 7 is a block diagram of an amplifying circuit 5 according to Embodiment 3 of the present invention. In the amplifying circuit 5 according to Embodiment 3, multiple positive polarity grayscale voltages (VPx, VPx+1) and multiple negative polarity grayscale voltages (VNx, VNx+1) from a DA converter 3 are inputted from terminals I1, I3, I2, and I4 of the amplifying circuit 5, respectively.

The amplifying circuit 5 of FIG. 7 into which the grayscale voltages are inputted from the four terminals I1, I3, I2, and I4 includes: a voltage follower 8 consisting of an input stage amplifying part 87 (consisting of four input stage amplifying parts, N1, N2, N3, and N4), a voltage follower connecting and polarity switching part 12, an output stage amplifying part 88 (consisting of four output stage amplifying parts, L1, L2, L3, and L4); and an output switching part 9.

For example, in the amplifying circuit 5 of FIG. 7, the voltage follower connecting and polarity switching part 12 is controlled by a polarity inverting signal POL and a strobe signal STB inputted from the outside so that in a first frame, a pair of an input stage amplifying part N1 and an output stage amplifying part LI, a pair of an input stage amplifying part N2 and an output stage amplifying part L2, a pair of an input stage amplifying part N3 and an output stage amplifying part L3, and a pair of an input stage amplifying part N4 and an output stage amplifying part L4 would respectively form a voltage follower. Then, analog signals inputted into the amplifying circuit 5 from the DA converter 3 through the terminals I1, I2, I3, and I4 are outputted to terminals S1, S2, S3, and S4, respectively.

In a second frame, the voltage follower connecting and polarity switching part 12 is controlled so that a pair of the input stage amplifying part N1 and the output stage amplifying part L2, a pair of the input stage amplifying part N2 and the output stage amplifying part L3, a pair of the input stage amplifying part N3 and the output stage amplifying part L4, and a pair of the input stage amplifying part N4 and the output stage amplifying part L1 would respectively form a voltage follower. Then, analog signals inputted into the amplifying circuit 5 from the DA converter 3 through the terminals I1, I2, I3, and I4 are outputted to the terminals S2, S3, S4, and S1, respectively.

In a third frame, the voltage follower connecting and polarity switching part 12 is controlled so that a pair of the input stage amplifying part N1 and the output stage amplifying part L3, a pair of the input stage amplifying part N2 and the output stage amplifying part L4, a pair of the input stage amplifying part N3 and the output stage amplifying part L1, and a pair of the input stage amplifying part N4 and the output stage amplifying part L2 would respectively form a voltage follower. Then, analog signals inputted into the amplifying circuit 5 from the DA converter 3 through the terminals I1, I2, I3, and I4 are outputted to the terminals S3, S4, S1, and S2, respectively.

In a fourth frame, the voltage follower connecting and polarity switching part 12 is controlled so that a pair of the input stage amplifying part N1 and the output stage amplifying part L4, a pair of the input stage amplifying part N2 and the output stage amplifying part L1, a pair of the input stage amplifying part N3 and the output stage amplifying part L2, and a pair of the input stage amplifying part N4 and the output stage amplifying part L3 would respectively form a voltage follower. Then, the analog signals inputted into the amplifying circuit 5 from the DA converter 3 through the terminals I1, I2, I3, and I4 are outputted to the terminals S4, S1, S2, and S3, respectively.

Description has been given using the input stage amplifying part 87 consisting of the four input stage amplifying parts N1 to N4 and the output stage amplifying part 88 consisting of the four output stage amplifying parts L1 to L4. However, the number and sequence of combination of the input stage amplifying part 87 and the output stage amplifying part 88 when switching the frame are merely an example for description, and will not be limited to this.

As has been described above, in the existing amplifying circuit 5 and display unit, in the case of a technique of providing the polarity switching part in a preceding stage of the voltage follower, the input stage of the amplifying circuit 5 needs to have the Rail-to-Rail property, and thus reduction in the area and reduction in the power consumption are prevented. In the case of a technique of providing the polarity switching part in a subsequent stage of the voltage follower, there is a tendency of increasing the area with enlargement of the screen size of the liquid crystal panel and high speed driving in recent years. Additionally, in order to switch the polarity switching part, it is necessary to build up and control complicated logic.

In the amplifying circuit 5 and display unit (for example, liquid crystal display) according to the present invention, the voltage follower is divided into components including the input stage amplifying part for high voltage, the input stage amplifying part for low voltage, and the multiple output stage amplifying parts. Then, an output relationship of the multiple output stage amplifying parts is changed depending on a control signal without changing an input relationship between the input stage amplifying part for high voltage and the input stage amplifying part for low voltage. Additionally, when the input stage amplifying part and the output stage amplifying part form one amplifying circuit, the switches are switched so that the amplifying circuit may form the voltage follower configuration. Accordingly, the input stage amplifying part does not need to have the Rail-to-Rail property. Thus, as compared with the technique of providing the polarity switching part 10 in a preceding stage of the voltage follower 8, reduction in the area and reduction in the power consumption can be attained. Moreover, as compared with the technique of providing the polarity switching and output switching part 11 in a subsequent stage of the voltage follower 8, reduction in the area can be attained, and it is not necessary to build up and control the complicated logic to switch the polarity.

A MOS transistor of the minimum size can be used for the switch of the voltage follower connecting and polarity switching part 12 according to the amplifying circuit 5 of the present invention. The size of the switch is approximately 1/30 compared with that of the polarity switching and output switching part 11 provided in a subsequent stage of the voltage follower. Thus, even when the number of switches increases by the voltage follower connecting and polarity switching part 12, increase in the number of switches does not cause increase in the area as compared with the conventional art.

The voltage follower connecting and polarity switching part 12 of the present invention may also serve as a switch for space offset cancellation that cancels fluctuation in the transistors that form the amplifying circuit 5.

While the first output stage amplifying part 85 and the second output stage amplifying part 86 have the same circuit configuration in the description above, naturally, the first output stage amplifying part 85 and the second output stage amplifying part 86 may have different circuit configurations from each other.

In the amplifying circuit 5 of an AB class drain output, control of the phase compensation capacitance switching part 13 in accordance with the external signal allows phase compensation by using one phase compensation capacitor, thus enabling further reduction in the area.

While the embodiments of the present invention have been described in detail above, a specific configuration is not limited to those in the above-mentioned embodiments. The present invention also includes modifications without deviating from the scope of the present invention. While the amplifying circuit 5 according to the present embodiments forms the voltage follower that drives the data line in the liquid crystal display in the above-mentioned description, naturally, the present invention is not limited to this. The amplifying circuit 5 may be used for other apparatuses, and may also be used in aspects other than the voltage follower.

What is claimed is:

1. An amplifying circuit, comprising:
a first input stage amplifying part that receives a first input signal only at a transistor differential pair of a first conductivity type;
a second input stage amplifying part that receives a second input signal different from the first input signal only at a transistor differential pair of a second conductivity type;
first and second output stage amplifying parts; and
a switching circuit that switches connections of the first input stage amplifying part and the second input stage amplifying part, with the first and second output stage amplifying parts, on the basis of external control signals.

2. An amplifying circuit that applies a voltage in a range from a first supply voltage to a second supply voltage higher than the first supply voltage, comprising:
a first input stage amplifying part consisting of a transistor differential pair of a first conductivity type;
a second input stage amplifying part consisting of a transistor differential pair of a second conductivity type;
first and second output stage amplifying parts; and
a switching circuit that switches a connection of each of the first input stage amplifying part and the second input stage amplifying part, between the first and second output stage amplifying parts, on the basis of external control signals, wherein
the first input stage amplifying part performs amplifying operation on a voltage if the voltage is approximately in a range from the second supply voltage, to a voltage obtained by adding the first supply voltage to a threshold voltage of a transistor that forms the transistor differential pair of the first conductivity type, and does not perform the amplifying operation if the voltage is out of the range,
the second input stage amplifying part performs amplifying operation on a voltage if the voltage is approximately in a range from the first supply voltage, to a voltage obtained by subtracting the second supply voltage by a threshold voltage of a transistor that forms the transistor differential pair of the second conductivity type, and does not perform the amplifying operation if the voltage is out of the range.

3. The amplifying circuit according to any one of claims 1 wherein
in response to an operation of the switching circuit,
in a first state, an output of the first input stage amplifying part is inputted into the first output stage amplifying part, and an output of the second input stage amplifying part is inputted into the second output stage amplifying part, and
in a second state, an output of the first input stage amplifying part is inputted into the second output stage amplifying part, and an output of the second input stage amplifying part is inputted into the first output stage amplifying part.

4. The amplifying circuit according to claim 3, wherein
in response to an operation of the switching circuit, two voltage followers are formed in each of the first and second states, in a way that:
in the first state, the output of the first output stage amplifying part is fed back to a second input terminal of the first input stage amplifying part that is different from an input terminal for receiving the input signal, and the output of the second output stage amplifying part is fed back to a second input terminal of the second input stage amplifying part that is different from an input terminal for receiving the input signal; and
in the second state, the output of the first output stage amplifying part is fed back to the second input terminal of the second input stage amplifying part, and the output of the second output stage amplifying part is fed back to the second input terminal of the first input stage amplifying part.

5. The amplifying circuit according to any one of claims 1 wherein
the first input stage amplifying part consists of a differential pair of N channel MOS transistors, and the second input stage amplifying part consists of a differential pair of P channel MOS transistors.

6. The amplifying circuit according to any one of claims 1 wherein
in response to an operation of the switching circuit, the first output stage amplifying part and the second output stage amplifying part switch and output signals with polarities different from each other from the respective output terminals.

7. The amplifying circuit according to any one of claims 2 wherein
each of the first and second output stage amplifying parts consists of a pair of a transistor of the first conductivity type and a transistor of the second conductivity type connected in series between the first supply voltage and the second supply voltage.

8. The amplifying circuit according to any one of claims 1 wherein
the external control signals are a polarity inverting signal POL and a strobe signal STB.

9. The amplifying circuit according to any one of claims 1 further comprising
a second switching circuit that switches configurations of the first output stage amplifying part and the second output stage amplifying part, on the basis of the external control signals.

10. The amplifying circuit according to any one of claims 1 wherein
each of the first and second output stage amplifying parts is capable of outputting both a voltage in an output voltage range of the first input stage amplifying part, and a voltage in an output voltage range of the second input stage amplifying part.

11. An amplifying circuit, comprising:
a plurality of first input stage amplifying parts each of which receives a first input signal only at a transistor differential pair of a first conductivity type;
a plurality of second input stage amplifying parts each of which receives a second input signal different from the first input signal only at a transistor differential pair of a second conductivity type;
a plurality of first and second output stage amplifying parts; and
a switching circuit that switches connection of each of the plurality of first input stage amplifying parts and the plurality of second input stage amplifying parts, with the plurality of first and second output stage amplifying parts, on the basis of external control signals.

12. An amplifying circuit that applies a voltage in a range from a first supply voltage to a second supply voltage higher than the first supply voltage, comprising:
a plurality of first input stage amplifying parts each consisting of a transistor differential pair of a first conductivity type;
a plurality of second input stage amplifying parts each consisting of a transistor differential pair of a second conductivity type;
a plurality of first and second output stage amplifying parts; and
a switching circuit that switches a connection of each of the plurality of first input stage amplifying parts and the plurality of second input stage amplifying parts, between the plurality of first and second output stage amplifying parts, on the basis of external control signals, wherein
the plurality of first input stage amplifying parts each perform amplifying operation on a voltage if the voltage is approximately in a range from the second supply voltage, to a voltage obtained by adding the first supply voltage to a threshold voltage of a transistor that forms the transistor differential pair of the first conductivity type, and does not perform the amplifying operation if the voltage is out of the range,
the plurality of second input stage amplifying parts each perform amplifying operation on a voltage if the voltage is approximately in a range from the first supply voltage, to a voltage obtained by subtracting the second supply voltage by a threshold voltage of a transistor that forms the transistor differential pair of the second conductivity type, and does not perform the amplifying operation if the voltage is out of the range.

13. A display unit on which an amplifying circuit is mounted, the amplifying circuit comprising:
a first input stage amplifying part that receives a first input signal only at a transistor differential pair of a first conductivity type;
a second input stage amplifying part that receives a second input signal different from the first input signal only at a transistor differential pair of a second conductivity type;
first and second output stage amplifying parts; and
a switching circuit that switches connections of the first input stage amplifying part and the second input stage amplifying part, with the first and second output stage amplifying parts, on the basis of external control signals.

14. A display unit on which an amplifying circuit is mounted, the amplifying circuit applying a voltage in a range from a first supply voltage to a second supply voltage higher than the first supply voltage, the amplifying circuit comprising:
a first input stage amplifying part consisting of a transistor differential pair of a first conductivity type;
a second input stage amplifying part consisting of a transistor differential pair of a second conductivity type;
first and second output stage amplifying parts; and
a switching circuit that switches a connection of each of the first input stage amplifying part and the second input stage amplifying part, between the first and second output stage amplifying parts, on the basis of external control signals, wherein
the first input stage amplifying part performs amplifying operation on a voltage if the voltage is approximately in a range from the second supply voltage, to a voltage obtained by adding the first supply voltage to a threshold voltage of a transistor that forms the transistor differential pair of the first conductivity type, and does not perform the amplifying operation if the voltage is out of the range,
the second input stage amplifying part performs amplifying operation on a voltage if the voltage is approximately in a range from the first supply voltage, to a voltage obtained by subtracting the second supply voltage by a threshold voltage of a transistor that forms the transistor differential pair of the second conductivity type, and does not perform the amplifying operation if the voltage is out of the range.
